(19) United States
(12) Patent Application Publication
(10) Pub. No.: US 2025/0149253 A1
(43) Pub. Date: May 8, 2025

(54) WIRING STRUCTURE AND AMPLIFIER

(71) Applicant: Sumitomo Electric Industries, Ltd., Osaka (JP)

(72) Inventors: Hayato SHIMIZU, Osaka-shi (JP); Sadanori ARAE, Osaka-shi (JP)

(73) Assignee: Sumitomo Electric Industries, Ltd., Osaka (JP)

(21) Appl. No.: 18/936,405

(22) Filed: Nov. 4, 2024

(30) Foreign Application Priority Data
Nov. 6, 2023 (JP) 2023-189222

(51) Int. Cl. H01G 4/33; H01G 4/005; H01L 23/522

(52) U.S. Cl. CPC H01G 4/33; H01G 4/005; H01L 23/5223; H01L 23/5226; H10D 1/68

(57) ABSTRACT

A wiring structure includes a MIM capacitor and a helical wiring. The wiring structure includes a substrate having a main surface and a back surface, a plurality of wiring layers sequentially stacked on or above the main surface. The plurality of wiring layers include a first wiring layer being a wiring layer closest to the substrate, a second wiring layer provided on or above the first wiring layer, and a third wiring layer provided on or above the second wiring layer. The MIM capacitor includes a first electrode included in the second wiring layer, a second electrode included in the third wiring layer, and a first electrically insulating layer provided between the first electrode and the second electrode. The helical wiring includes a first wiring included in the first wiring layer, a second wiring included in the second wiring layer, and a third wiring included in the third wiring layer.

### CROSS REFERENCE TO RELATED APPLICATIONS

This application claims priority based on Japanese Patent Application No. 2023-189222 filed on Nov. 6, 2023, and the entire contents of the Japanese patent application are incorporated herein by reference.

### TECHNICAL FIELD

The present disclosure relates to a wiring structure and an amplifier.

### BACKGROUND

Patent literature (WO 2008/016089) discloses an inductor formed over a plurality of lead layers on a substrate. The inductor is formed by mutually connecting a plurality of C-shaped leads included in the plurality of lead layers.

### SUMMARY

A wiring structure according to the present disclosure is a wiring structure including a MIM capacitor and a helical wiring. The wiring structure includes a substrate having a main surface and a back surface, and a plurality of wiring layers sequentially stacked on or above the main surface. The plurality of wiring layers include a first wiring layer being a wiring layer closest to the substrate, a second wiring layer provided on or above the first wiring layer, and a third wiring layer provided on or above the second wiring layer. The MIM capacitor includes a first electrode included in the second wiring layer, a second electrode included in the third wiring layer, and a first electrically insulating layer provided between the first electrode and the second electrode. The helical wiring includes a first wiring included in the first wiring layer, a second wiring included in the second wiring layer, and a third wiring included in the third wiring layer.

### BRIEF DESCRIPTION OF THE DRAWINGS

FIG. 1 is a diagram showing a cross-sectional structure of a wiring structure according to a first embodiment.

FIG. 2 is a perspective view showing a three-dimensional structure of an inductor.

FIG. 3 is a circuit diagram showing a configuration of an amplifier including a wiring structure.

FIG. 4 is a graph showing a relationship between the number of wiring layers and the area in an inductor required to obtain the same inductance, and a relationship between the number of wiring layers in an inductor and the deposition time of electrically insulating layers.

FIG. 5 is a circuit diagram of a passive element according to a second embodiment.

FIG. 6 is a plan view of a wiring structure included in a passive element.

FIG. 7 is a diagram showing a cross-sectional structure of a wiring structure.

FIG. 8 is a diagram showing a cross-sectional structure of a wiring structure according to a comparative example.

### DETAILED DESCRIPTION

For example, in a semiconductor device such as a semiconductor amplifier, a plurality of wiring layers on a substrate may be used to form a metal-insulator-metal (MIM) capacitor and a helical wiring as an inductor. In this case, when a lower electrode of the MIM capacitor is formed using a first wiring layer, the flatness of the lower electrode may be impaired. The impaired flatness of the lower electrode may result in an increase in variation in the thickness of the electrically insulating layer formed between the lower electrode and the upper electrode, and electric field may increase locally at a portion where the thickness of the electrically insulating layer is small. This may lead to variations in characteristics of the semiconductor device and a decrease in reliability of the semiconductor device. In addition, the helical wiring as the inductor often requires more wiring layers than MIM capacitors, and since more wiring layers require more time to manufacture, it is desirable to reduce the total number of wiring layers.

The present disclosure has been made in view of the above problems, and an object of the present disclosure is to reduce a local increase in electric field in a MIM capacitor and to reduce the total number of wiring layers, in a wiring structure and an amplifier including a MIM capacitor and a helical wiring.

### Description of Embodiments of Present Disclosure

First, the contents of embodiments of the present disclosure will be listed and explained.

(1) A wiring structure according to one aspect of the present disclosure is a wiring structure including a MIM capacitor and a helical wiring. The wiring structure includes a substrate having a main surface and a back surface, and a plurality of wiring layers sequentially stacked on or above the main surface. The plurality of wiring layers include a first wiring layer being a wiring layer closest to the substrate, a second wiring layer provided on or above the first wiring layer, and a third wiring layer provided on or above the second wiring layer. The MIM capacitor includes a first electrode included in the second wiring layer, a second electrode included in the third wiring layer, and a first electrically insulating layer provided between the first electrode and the second electrode. The helical wiring includes a first wiring included in the first wiring layer, a second wiring included in the second wiring layer, and a third wiring included in the third wiring layer. In this wiring structure, the first electrode (lower electrode) of the MIM capacitor is included in the second wiring layer provided on or above the first wiring layer, not in the first wiring layer which is the lowermost layer among the plurality of wiring layers on or above the substrate. Usually, an electrically insulating layer is interposed between the first wiring layer and the second wiring layer. Irregularities of a surface of the first wiring layer are gradually eliminated on a surface of the electrically insulating layer when the electrically insulating layer is stacked. Thus, since the first electrode is included in the second wiring layer, a surface of the first electrode can be made flat, compared to a case where the first electrode is included in the first wiring layer. Thus, the first electrically insulating layer formed between the first electrode and the second electrode has a small variation in thickness, and a local increase in the electric field in the MIM capacitor is reduced. In addition, the helical wiring (inductor) includes the first wiring of the first wiring layer which is the lowermost layer among the plurality of wiring layers, and the second wiring and the third wiring which are respectively included in the second wiring layer and the third wiring layer that are also used in the MIM capacitor. Thus, the total number of wiring layers can be reduced.

(2) The wiring structure according to the above (1) may further include a fourth wiring provided between the MIM capacitor and the substrate and included in the first wiring layer, and one or more first vias connecting the first electrode to the fourth wiring. In this case, the first electrode can be electrically connected to the fourth wiring included in the first wiring layer with low inductance.

(3) The wiring structure according the above (2) may further include a metal film provided on the back surface, and a second via provided to penetrate the substrate between the main surface and the back surface and connecting the metal film to the fourth wiring. The second via may overlap the MIM capacitor and the fourth wiring when viewed in a direction perpendicular to the main surface. In this case, the first electrode of the MIM capacitor can be electrically connected to the metal film (for example, a reference potential line) provided on the back surface. In addition, as compared with the case where the second via is provided at a position not overlapping the MIM capacitor when viewed in the direction perpendicular to the main surface, the area on the main surface required for the wiring structure can be reduced, and the wiring structure can be miniaturized.

(4) In the wiring structure according to the above (1) to (3), the helical wiring may further include a plurality of third vias disposed in a distributed manner over an entire region of the second wiring and the third wiring and connecting the second wiring to the third wiring. In this case, the potential of the second wiring and the potential of the third wiring become closer to uniform over the entire region. Thus, since the inter-wiring capacitance generated by the potential difference between the second wiring and the third wiring can be reduced, the capacitive component (parasitic capacitance) of the helical wiring (inductor) can be reduced. In addition, the deviation of the current flow can be reduced between the second wiring and the third wiring. Further, by integrating the second wiring and the third wiring, even when the thickness of the second wiring and the thickness of the third wiring are reduced, a decrease in the allowable current density and an increase in the wiring resistance can be reduced.

(5) In the wiring structure according to the above (4), each of thicknesses of the second wiring and the third wiring may be smaller than a thickness of the first wiring. In this case, as in the above (4), by connecting the second wiring to the third wiring via the plurality of third vias, a partial increase in the current density of the helical wiring (inductor) can be reduced. Further, by reducing the thicknesses of the second wiring and the third wiring, the time required for forming wiring can be shortened.

(6) In the wiring structure according to the above (5), a thickness of a wiring in the second wiring layer may be smaller than a thickness of a wiring in the third wiring layer. In this case, the possibility of disconnection of the wiring in the third wiring layer extending from the second electrode of the MIM capacitor can be reduced, and the wiring in the second wiring layer can be thinned to shorten the time for forming the second wiring layer.

(7) In the wiring structure according to the above (5), a sum of the thicknesses of the second wiring and the third wiring may be equal to the thickness of the first wiring. In this case, the current density of the helical wiring (inductor) can be made uniform.

(8) In the wiring structure according to the above (4), the plurality of wiring layers may further include a fourth wiring layer stacked on or above the third wiring layer. The helical wiring may be constituted by further including a fifth wiring included in the fourth wiring layer. In this case, the helical wiring (inductor) having a larger inductance can be easily designed.

(9) In the wiring structure according to the above (8), a thickness of the fifth wiring may be equal to or more than a thickness of the first wiring. Since the fifth wiring is included in the fourth wiring layer which is the uppermost layer, the time for forming the electrically insulating layer does not become long even when the fifth wiring is formed thick. By forming the fifth wiring to be thick, the current density of the fifth wiring can be sufficiently reduced.

(10) In the wiring structure according to the above (8), the first wiring, the second wiring, the third wiring, and the fifth wiring each may have a ring shape partially having a gap, and may be arranged such that centers of the ring shapes are located on a common axis perpendicular to the main surface. The gap of the second wiring and the gap of the third wiring may be arranged in a direction perpendicular to the main surface. The wiring structure may further include a fourth via and a fifth via. The fourth via connects an end portion of the first wiring to an end portion of the second wiring. The fifth via connects a second end portion of the third wiring located opposite to a first end portion of the third wiring located above the end portion of the second wiring to an end portion of the fifth wiring. For example, the helical wiring can be formed by such a structure.

(11) In the wiring structure according to any one of the above (1) to (7), the plurality of wiring layers may further include a fourth wiring layer stacked on or above the third wiring layer. The fourth wiring layer may include a sixth wiring provided above the MIM capacitor. For example, by providing the wiring in the fourth wiring layer also above the MIM capacitor in this way, the area on the main surface required for the wiring structure can be reduced, and the wiring structure can be miniaturized.

(12) The wiring structure according to the above (1) to (11) may further include a second electrically insulating layer interposed between the first wiring layer and the second wiring layer, and a third electrically insulating layer interposed between the second wiring layer and the third wiring layer. A thickness of the first electrically insulating layer may be smaller than each of thicknesses of the second electrically insulating layer and the third electrically insulating layer. A dielectric constant of the first electrically insulating layer may be larger than each of dielectric constants of the second electrically insulating layer and the third electrically insulating layer. In this case, the capacitance of the MIM capacitor per unit area can be increased. Thus, the area on the main surface required for the wiring structure can be reduced, and the wiring structure can be miniaturized.

(13) An amplifier according to one aspect of the present disclosure includes the wiring structure according to any one of the above (1) to (12), and a transistor provided on or above the substrate shared with the wiring structure. According to this amplifier, by providing any one of the above-described wiring structures, it is possible to reduce a local increase in the electric field in the MIM capacitor and to reduce the total number of wiring layers.

### DETAILS OF EMBODIMENTS OF PRESENT DISCLOSURE

Specific examples of a wiring structure and an amplifier of the present disclosure will be described below with reference to the drawings. The present invention is not limited to these examples, but is defined by the scope of the claims, and is intended to include all modifications within the meaning and scope equivalent to the scope of the claims. In the following description, the same elements are denoted by the same reference numerals in the description of the drawings, and redundant description will be omitted.

### First Embodiment

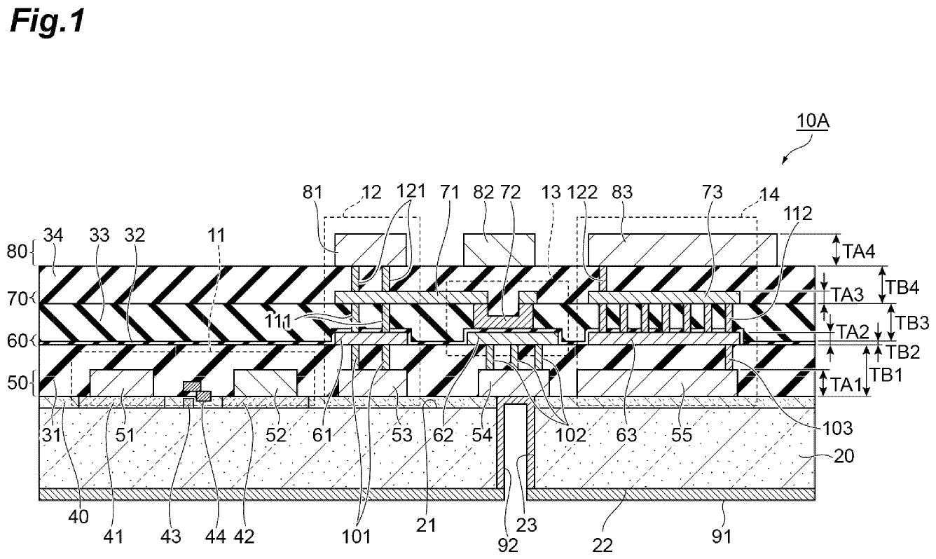

FIG. 1 is a diagram showing a cross-sectional structure of a wiring structure 10A according to the embodiment. As shown in FIG. 1, wiring structure 10A includes a substrate 20 having a main surface 21 and a back surface 22, and an electrically insulating film 40. Substrate 20 is, for example, a semiconductor substrate. Substrate 20 is, for example, a III-V group compound semiconductor substrate or a substrate on which a III-V group compound semiconductor can be grown. Main surface 21 and back surface 22 are parallel to each other and are both flat. Substrate 20 has a hole 23 penetrating substrate 20 from main surface 21 to back surface 22.

Electrically insulating film 40 is provided on main surface 21 of substrate 20 and is in contact with main surface 21. Electrically insulating film 40 is mainly made of, for example, a silicon compound such as SiO₂ or SiN. Electrically insulating film 40 has an opening communicating with hole 23.

Wiring structure 10A further includes a plurality of wiring layers including a first wiring layer 50, a second wiring layer 60, a third wiring layer 70, and a fourth wiring layer 80. In the illustrative example, the plurality of wiring layers is composed of first wiring layer 50, second wiring layer 60, third wiring layer 70, and fourth wiring layer 80. In other words, wiring structure 10A does not include any wiring layer other than first wiring layer 50, second wiring layer 60, third wiring layer 70, and fourth wiring layer 80. First wiring layer 50 is a wiring layer closest to substrate 20 among the plurality of wiring layers. Electrically insulating film 40 is interposed between first wiring layer 50 and main surface 21, and is in contact with both first wiring layer 50 and main surface 21. Second wiring layer 60 is provided on or above first wiring layer 50. Third wiring layer 70 is provided on or above second wiring layer 60. Fourth wiring layer 80 is provided on or above third wiring layer 70. The wiring in first wiring layer 50, the wiring in second wiring layer 60, the wiring in third wiring layer 70, and the wiring in fourth wiring layer 80 include at least one metal material of Au, Ti, Al, Ta, W, Cu, Pt, Mo, Ni, Pd, and Cr, for example.

A thickness TA2 of the wiring in second wiring layer 60 is equal to or smaller than a thickness TA3 of the wiring in third wiring layer 70. A ratio of the thickness TA2 of the wiring in second wiring layer 60 to the thickness TA3 of the wiring in third wiring layer 70 (TA2/TA3) is, for example, ½ to 1. In one example, the thickness TA2 is 1 μm or 2 μm, and the thickness TA3 is 2 μm.

The thickness TA2 of the wiring in second wiring layer 60 and the thickness TA3 of the wiring in third wiring layer 70 are smaller than a thickness TA1 of the wiring in first wiring layer 50. A ratio of the thickness TA2 of the wiring in second wiring layer 60 to the thickness TA1 of the wiring in first wiring layer 50 (TA2/TA1) is, for example, ¼ to ½. A ratio of the thickness TA3 of the wiring in third wiring layer 70 to the thickness TA1 of the wiring in first wiring layer 50 (TA3/TA1) is, for example, ½ to ⅔. In one example, the thickness TA1 is 3 μm or 4 μm. A sum of the thickness TA2 of the wiring in second wiring layer 60 and the thickness TA3 of the wiring in third wiring layer 70 (TA2+TA3) may be equal to the thickness TA1 of the wiring in first wiring layer 50. A thickness TA4 of the wiring in fourth wiring layer 80 is equal to or more than the thickness TA1 of the wiring in first wiring layer 50.

Wiring structure 10A further includes an electrically insulating layer 31 (a second electrically insulating layer), an electrically insulating layer 32 (a first electrically insulating layer), an electrically insulating layer 33, and an electrically insulating layer 34. Electrically insulating layer 32 is provided on electrically insulating layer 31, electrically insulating layer 33 is provided on electrically insulating layer 32, and electrically insulating layer 34 is provided on electrically insulating layer 33. Electrically insulating layer 31 is interposed between first wiring layer 50 and second wiring layer 60. In a part of first wiring layer 50 where no wiring is provided, electrically insulating layer 31 is in contact with electrically insulating film 40. Electrically insulating layers 32 and 33 are interposed between second wiring layer 60 and third wiring layer 70. In a part of second wiring layer 60 where no wiring is provided, electrically insulating layer 32 is in contact with electrically insulating layer 31. Electrically insulating layer 33 is provided on electrically insulating layer 32 and is in contact with electrically insulating layer 32. Electrically insulating layer 34 is interposed between third wiring layer 70 and fourth wiring layer 80. In a part of third wiring layer 70 where no wiring is provided, electrically insulating layer 34 is in contact with electrically insulating layer 33. A dielectric constant of electrically insulating layer 32 is larger than a dielectric constant of each of electrically insulating layers 31, 33 and 34. Electrically insulating layers 31, 33 and 34 include a dielectric material, such as an insulating material containing Si such as SiO₂, SiN or SiON, or a resinous material such as polyimide. Electrically insulating layer 32 includes a dielectric material, such as an insulating material containing Si such as SiO₂, SiN, or SiON, or a resinous material such as polyimide, or a metallic oxide such as hafnium oxide (HfO₂) or aluminum oxide (Al₂O₃). A thickness TB2 of electrically insulating layer 32 is smaller than each thickness TB1, TB3 and TB4 of electrically insulating layers 31, 33 and 34. The thickness TB1 of electrically insulating layer 31 is more than each thicknesses TB2, TB3 and TB4 of electrically insulating layers 32, 33, and 34. A ratio of the thickness TB2 of electrically insulating layer 32 to the thickness TB1 of electrically insulating layer 31 (TB2/TB1) is, for example, 0.001 to 0.5. In one example, the thicknesses TB1, TB2, TB3 and TB4 are 6 μm, 0.23 μm, 3 μm and 4 μm, respectively.

Wiring structure 10A includes a wiring portion 12, a MIM capacitor 13, and an inductor 14 which is a helical wiring. A transistor 11 is provided separately from wiring structure 10A. Transistor 11, wiring portion 12, MIM capacitor 13, and inductor 14 are provided in regions different from each other when viewed from a direction perpendicular to main surface 21.

Transistor 11 of the embodiment is a high electron mobility transistor (HEMT). Transistor 11 includes a source electrode 41, a drain electrode 42, a gate electrode 43, and a field plate 44. Substrate 20 includes a channel layer and an electron supply layer (not shown). Source electrode 41 and drain electrode 42 are provided in a source opening and a drain opening formed in electrically insulating film 40, respectively, and form ohmic contact with the channel layer or the electron supply layer of substrate 20. Gate electrode 43 is provided in a gate opening formed in electrically insulating film 40 and forms a Schottky contact with substrate 20. Field plate 44 is insulated from gate electrode 43, and is provided above gate electrode 43 and between gate electrode 43 and drain electrode 42.

Transistor 11 further includes a source wiring 51 and a drain wiring 52. Both source wiring 51 and drain wiring 52 are included in first wiring layer 50. Source wiring 51 is provided on source electrode 41 and is in contact with source electrode 41. Drain wiring 52 is provided on drain electrode 42 and is in contact with drain electrode 42.

Wiring portion 12 includes wirings 53, 61, 71 and 81, one or more vias 101, one or more vias 111, and one or more vias 121. Wiring 53 is included in first wiring layer 50. Wiring 61 is included in second wiring layer 60. Vias 101 penetrate electrically insulating layer 31 and connect wiring 61 to wiring 53. Wiring 71 is included in third wiring layer 70. Vias 111 penetrate electrically insulating layers 32 and 33 and connect wiring 71 to wiring 61. Wiring 81 is included in fourth wiring layer 80. Vias 121 penetrate electrically insulating layer 34 and connect wiring 81 to wiring 71. Wiring portion 12 shown in FIG. 1 schematically represents the wirings of the portion other than transistor 11, MIM capacitor 13, and inductor 14 in wiring structure 10A.

MIM capacitor 13 includes a lower electrode 62 (first electrode), an upper electrode 72 (second electrode), and electrically insulating layer 32. Lower electrode 62 is included in second wiring layer 60. Upper electrode 72 is included in third wiring layer 70. Electrically insulating layer 32 is provided between lower electrode 62 and upper electrode 72. The capacitance of MIM capacitor 13 depends on the area where lower electrode 62 and upper electrode 72 face each other, the dielectric constant of electrically insulating layer 32, and the thickness of electrically insulating layer 32.

Upper electrode 72 is formed integrally with wiring 71 included in third wiring layer 70. Specifically, an opening is formed in a region of electrically insulating layer 33 above lower electrode 62, and upper electrode 72 is formed on side surface of the opening and on a bottom surface of the opening, that is, on electrically insulating layer 32 exposed from electrically insulating layer 33. Wiring 71 covers a part of upper electrode 72, and the part of upper electrode 72 is in contact with wiring 71. Thus, upper electrode 72 protrudes from wiring 71 toward substrate 20 and is provided at the same height as electrically insulating layer 33, but is connected to wiring 71, and thus is assumed to be included in third wiring layer 70 here.

Wiring structure 10A of the embodiment further includes wiring 54 (fourth wiring), one or more vias 102 (first via), a wiring 82 (sixth wiring), a metal film 91, and a via 92 (second via).

Wiring 54 is included in first wiring layer 50. Wiring 54 is provided between MIM capacitor 13 and substrate 20. Vias 102 penetrate electrically insulating layer 31 between lower electrode 62 and wiring 54, and connect lower electrode 62 to wiring 54. Vias 102 overlap lower electrode 62 and wiring 54 when viewed in the direction perpendicular to main surface 21 of substrate 20.

Metal film 91 is provided on back surface 22 of substrate 20. Metal film 91 is bonded, for example, to a reference potential line on a wiring substrate on which wiring structure 10A is mounted with a conductive bonding material (for example, silver paste), and is set to a reference potential. Via 92 is provided to penetrate substrate 20 between main surface 21 and back surface 22. In the illustrative example, via 92 is provided on the side surface of hole 23 formed in substrate 20 and in the opening of electrically insulating film 40 communicating with hole 23. Via 92 extends from back surface 22 of substrate 20 to a surface of electrically insulating film 40. One end of via 92 is connected to a wiring 54 by being in contact with wiring 54, and the other end of via 92 is connected to metal film 91 by being in contact with metal film 91. Thus, via 92 connects metal film 91 to wiring 54. Via 92 is provided at a position overlapping MIM capacitor 13 and wiring 54 when viewed in the direction perpendicular to main surface 21.

Wiring 82 is included in fourth wiring layer 80. Wiring 82 is part of many wirings that connect various circuit elements provided in wiring structure 10A. Wiring 82 is provided above MIM capacitor 13. In other words, wiring 82 is provided at a position overlapping MIM capacitor 13 when viewed in the direction perpendicular to main surface 21.

Inductor 14 includes a wiring 55 (first wiring), a wiring 63 (second wiring), a wiring 73 (third wiring), and a wiring 83 (fifth wiring). Wiring 55 is included in first wiring layer 50. Wiring 63 is included in second wiring layer 60. Wiring 73 is included in third wiring layer 70. Wiring 73 has the same planar shape as the planar shape of wiring 63, and overlaps wiring 63 when viewed in the direction perpendicular to main surface 21. Wiring 83 is included in fourth wiring layer 80. Thus, a thickness TA2 of wiring 63 is equal to or smaller than a thickness TA3 of wiring 73. The thickness TA2 of wiring 63 and the thickness TA3 of wiring 73 are smaller than a thickness TA1 of wiring 55. A sum of the thickness TA2 of wiring 63 and the thickness TA3 of wiring 73 (TA2+TA3) may be equal to the thickness TA1 of wiring 55. A thickness TA4 of wiring 83 is equal to or more than the thickness TA1 of wiring 55. The thickness of each of wiring 55, wiring 63, wiring 73, and wiring 83 is determined according to the frequency to be used.

Inductor 14 further includes one or more vias 103, a plurality of vias 112 (third via), and one or more vias 122. Via 103 penetrates electrically insulating layer 31 between wiring 63 and wiring 55. Via 103 connects one end of wiring 63 to one end of wiring 55. Via 122 penetrates electrically insulating layer 34 between wiring 83 and wiring 73. Via 122 connects one end of wiring 83 to one end of wiring 73. The plurality of vias 112 are disposed in a distributed manner over an entire region of wiring 63 and wiring 73, and connect wiring 63 to wiring 73. The entire region of wiring 63 and wiring 73 refers to the entire region of wiring 63 and wiring 73 mainly in the direction of extension, and more specifically, refers to a region corresponding to 95% or more of a length of wiring 63 and wiring 73 in the direction of extension. In other words, the plurality of vias 112 are provided to integrate wiring 63 and wiring 73 as a single wiring.

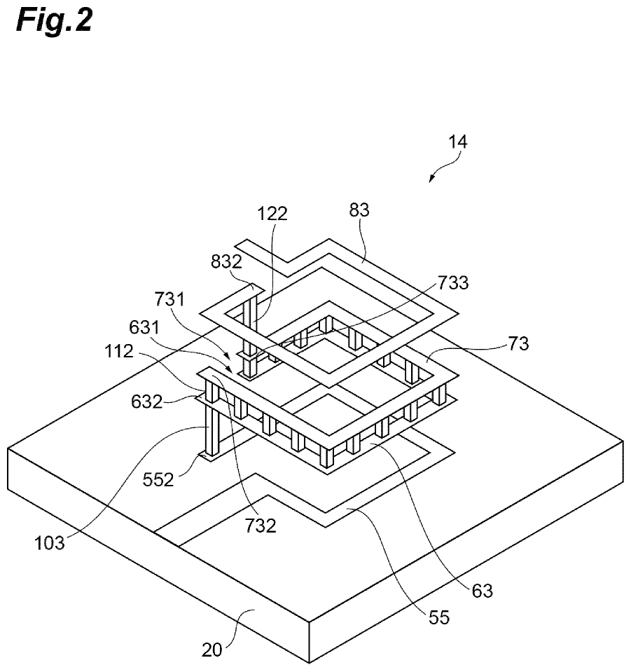

FIG. 2 is a perspective view showing a three-dimensional structure of inductor 14. As shown in FIG. 2, inductor 14 formed of a helical wiring comprises by connecting wiring 55, via 103, wirings 63 and 73, via 122, and wiring 83 in this order. Specifically, wiring 55, wiring 63, wiring 73, and wiring 83 each have a ring shape partially having a gap. Wiring 55, wiring 63, wiring 73, and wiring 83 are arranged such that the centers of the ring shapes are located on a common axis line perpendicular to main surface 21. A gap 631 of wiring 63 and a gap 731 of wiring 73 are arranged in a direction perpendicular to main surface 21. Via 103 connects an end portion 552 of wiring 55 and an end portion 632 of wiring 63. Via 122 connects an end portion 733 (second end portion) of wiring 73 located opposite to an end portion 732 (first end portion) of wiring 73 located above end portion 632 of wiring 63, and an end portion 832 of wiring 83.

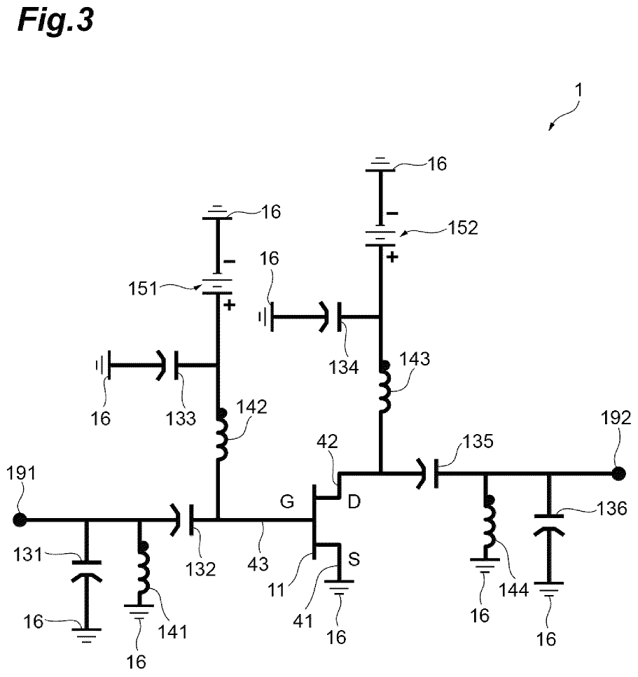

FIG. 3 is a circuit diagram showing a configuration of an amplifier 1 including wiring structure 10A. Amplifier 1 includes transistor 11, an input terminal 191, an output terminal 192, capacitors 131 to 136, inductors 141 to 144, bias power supplies 151 and 152, and a reference potential line 16. The structure of transistor 11 is as described above. The structure of at least one of the capacitors among capacitors 131 to 136 is the same as the structure of MIM capacitor 13 described above. The structure of at least one of the inductors among inductors 141 to 144 is the same as the structure of inductor 14 described above.

A first electrode of capacitor 132 is connected to input terminal 191. A second electrode of capacitor 132 is connected to gate electrode 43 of transistor 11. Thus, gate electrode 43 of transistor 11 receives a signal before amplification via capacitor 132. Capacitor 132 acts as a coupling capacitor for the signal before amplification.

A first electrode of capacitor 135 is connected to drain electrode 42 of transistor 11. A second electrode of capacitor 135 is connected to output terminal 192. Thus, a signal after amplification is output from drain electrode 42 of transistor 11 via capacitor 135. Capacitor 135 acts as a coupling capacitor for the signal after amplification.

Capacitor 131 and inductor 141 are connected in parallel to each other between input terminal 191 and reference potential line 16. Capacitor 131 and inductor 141 act as a filter for the signal before amplification. Capacitor 136 and inductor 144 are connected in parallel to each other between output terminal 192 and reference potential line 16. Capacitor 136 and inductor 144 act as a filter for the signal after amplification.

Capacitor 133 is connected between the positive electrode of bias power supply 151 and reference potential line 16. Inductor 142 is connected between the positive electrode of bias power supply 151 and gate electrode 43 of transistor 11. Capacitor 133 and inductor 142 act as a filter for the input bias voltage supplied from bias power supply 151 to gate electrode 43. Capacitor 134 is connected between the positive electrode of bias power supply 152 and reference potential line 16.

Inductor 143 is connected between the positive electrode of bias power supply 152 and drain electrode 42 of transistor 11. Capacitor 134 and inductor 143 act as a filter for the output bias voltage supplied from bias power supply 152 to drain electrode 42.

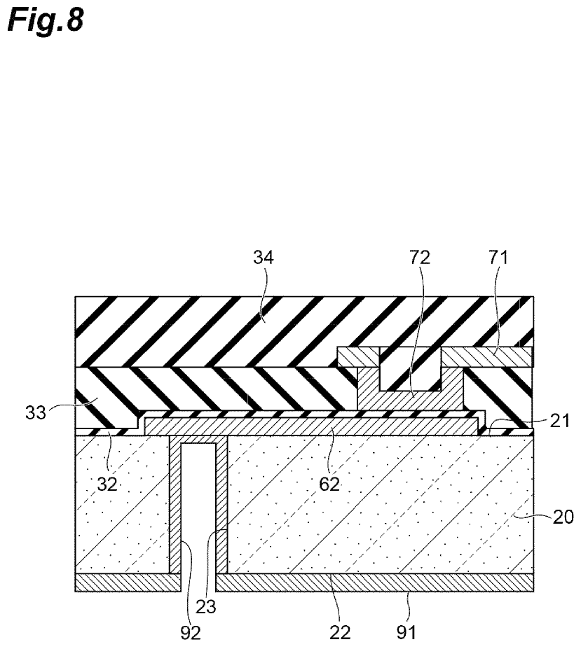

The effects obtained by wiring structure 10A and amplifier 1 of the embodiment having the above configuration will be described with comparative examples. FIG. 8 is a diagram showing a cross-sectional structure of a wiring structure according to a comparative example. In this comparative example, lower electrode 62 of MIM capacitor 13 is included in first wiring layer 50. Upper electrode 72 of MIM capacitor 13 is included in second wiring layer 60. In this case, the flatness of lower electrode 62 may be impaired. The impaired flatness of lower electrode 62 may result in an increase in variation in the thickness of electrically insulating layer 32 formed between lower electrode 62 and upper electrode 72, and electric field locally increases at a portion where the thickness of electrically insulating layer 32 is small. This leads to variations in the characteristics of the semiconductor device and a decrease in the reliability of the semiconductor device.

In contrast, in the embodiment, in wiring structure 10A, lower electrode 62 of MIM capacitor 13 is included in second wiring layer 60 provided on or above first wiring layer 50, not in first wiring layer 50 which is the lowermost layer among the plurality of wiring layers on or above substrate 20. Usually, electrically insulating layer 31 is interposed between first wiring layer 50 and second wiring layer 60. Irregularities of the surface of first wiring layer 50 are gradually eliminated on the surface of electrically insulating layer 31 when electrically insulating layer 31 is stacked. Therefore, by including lower electrode 62 in second wiring layer 60, a surface of lower electrode 62 can be made flat, compared to a case where lower electrode 62 is included in first wiring layer 50. Thus, electrically insulating layer 32 formed between lower electrode 62 and upper electrode 72 has a small variation in thickness, and a local increase in the electric field in MIM capacitor 13 is reduced.

In addition, in the embodiment, inductor 14 includes wiring 55 of first wiring layer 50 which is the lowermost layer among the plurality of wiring layers, and wiring 63 and wiring 73 which are included in second wiring layer 60 and third wiring layer 70, respectively, which are also used in MIM capacitor 13. Thus, in wiring structure 10A including both MIM capacitor 13 and inductor 14, the total number of wiring layers can be reduced.

As in the embodiment, wiring structure 10A may include wiring 54 provided between MIM capacitor 13 and substrate 20 and included in first wiring layer 50, and one or more vias 102 connecting lower electrode 62 to wiring 54. In this case, lower electrode 62 can be electrically connected to wiring 54 included in first wiring layer 50 with low inductance.

As in the embodiment, wiring structure 10A may include metal film 91 provided on back surface 22, and via 92 provided to penetrate substrate 20 between main surface 21 and back surface 22 and connecting metal film 91 to wiring 54. Via 92 may overlap MIM capacitor 13 and wiring 54 when viewed in the direction perpendicular to main surface 21. In this case, lower electrode 62 of MIM capacitor 13 can be electrically connected to metal film 91 (for example, a reference potential line) provided on back surface 22. In addition, as compared with the case where via 92 is provided at a position not overlapping MIM capacitor 13 when viewed in the direction perpendicular to main surface 21 (see FIG. 8), the area on main surface 21 required for wiring structure 10A can be reduced, and wiring structure 10A can be miniaturized.

As in the embodiment, inductor 14 may include a plurality of vias 112 disposed in a distributed manner over the entire region of wiring 63 and wiring 73 and connecting wiring 63 to wiring 73. In this case, the potential of wiring 63 and the potential of wiring 73 become closer to uniform over the entire region. Thus, since the inter-wiring capacitance generated by the potential difference between wiring 63 and wiring 73 can be reduced, the capacitive component (parasitic capacitance) of inductor 14 can be reduced. In addition, the deviation of the current flow can be reduced between wiring 63 and wiring 73. Furthermore, by integrating wiring 63 and wiring 73, even when the thickness TA2 of wiring 63 and the thickness TA3 of wiring 73 are reduced, a decrease in the allowable current density and an increase in the wiring resistance can be reduced.

As in the embodiment, the thicknesses TA2 and TA3 of respective wiring 63 and wiring 73 may be smaller than the thickness TA1 of wiring 55. In this case, by connecting wiring 63 to wiring 73 via the plurality of vias 112 as described above, a partial increase in the current density of inductor 14 can be reduced. Further, by reducing the thicknesses TA2 and TA3 of wiring 63 and wiring 73, respectively, the time required for forming wiring can be shortened.

As in the embodiment, the thickness TA2 of the wiring in second wiring layer 60 may be smaller than the thickness TA3 of the wiring in third wiring layer 70. In this case, the possibility of disconnection of the wiring in third wiring layer 70 extending from upper electrode 72 of MIM capacitor 13 can be reduced, and the wiring in second wiring layer 60 can be thinned to shorten the time for forming second wiring layer 60.

As in the embodiment, the sum of the thicknesses of wiring 63 and wiring 73 (TA2+TA3) may be equal to the thickness TA1 of wiring 55. In this case, the current density of inductor 14 can be made uniform.

As in the embodiment, the plurality of wiring layers of wiring structure 10A may include fourth wiring layer 80 stacked on or above third wiring layer 70. Inductor 14 may include wiring 83 included in fourth wiring layer 80. In this case, inductor 14 having a larger inductance can be easily designed.

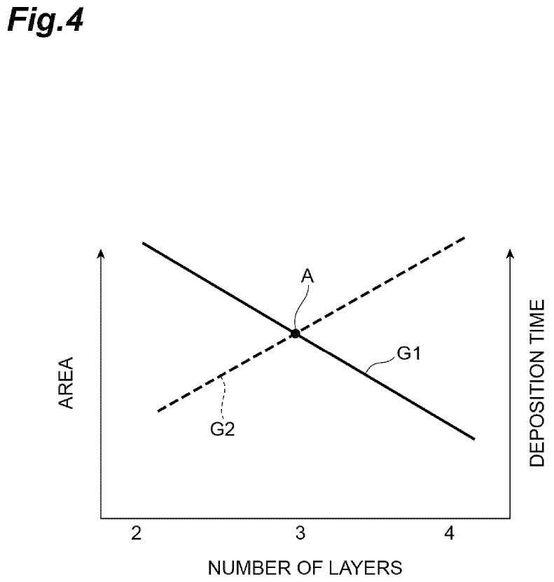

FIG. 4 is a graph showing a relationship between the number of wiring layers and the area in the inductor required to obtain the same inductance, and a relationship between the number of wiring layers in the inductor and the deposition time of the electrically insulating layers. In FIG. 4, a straight line G1 shows the relationship between the number of wiring layers and the area, and a straight line G2 shows the relationship between the number of wiring layers and the deposition time. As shown in the figure, the area of the inductor decreases as the number of wiring layers increases. Meanwhile, the deposition time of the electrically insulating layers increases as the number of wiring layers increases. When the number of wiring layers is 3 (point A in the figure), the area and the deposition time are balanced in the best way. That is, inductor 14 comprises three wiring layers of (1) wiring 55, (2) the integral wiring by wirings 63 and 73, and (3) wiring 83, and thus the balance between the area and the deposition time is optimized, and the manufacturing cost of wiring structure 10A can be reduced.

As in the embodiment, the thickness TA4 of wiring 83 may be equal to or more than the thickness TA1 of wiring 55. Since wiring 83 is included in fourth wiring layer 80 which is the uppermost layer, the time for forming the electrically insulating layer does not become long even when wiring 83 is formed thick. By forming wiring 83 thick, the current density of wiring 83 can be sufficiently reduced.

As in the embodiment, wiring 55, wiring 63, wiring 73, and wiring 83 may each have a ring shape partially having a gap. Wiring 55, wiring 63, wiring 73, and wiring 83 may be arranged such that the centers of the ring shapes are located on a common axis line perpendicular to main surface 21. Gap 631 of wiring 63 and gap 731 of wiring 73 may be arranged in a direction perpendicular to main surface 21. Via 103 may connect end portion 552 of wiring 55 and end portion 632 of wiring 63. Via 122 may connect end portion 733 (second end portion) of wiring 73 located opposite to end portion 732 (first end portion) of wiring 73 located above end portion 632 of wiring 63, and end portion 832 of wiring 83. For example, inductor 14 can be formed by such a structure.

As in the embodiment, fourth wiring layer 80 may include wiring 82 provided above MIM capacitor 13. For example, by providing the wiring in fourth wiring layer 80 also above MIM capacitor 13 in this way, the area on main surface 21 required for wiring structure 10A can be reduced, and wiring structure 10A can be miniaturized.

As in the embodiment, wiring structure 10A may include electrically insulating layer 31 interposed between first wiring layer 50 and second wiring layer 60, and electrically insulating layer 33 interposed between second wiring layer 60 and third wiring layer 70. The thickness TB2 of electrically insulating layer 32 may be smaller than thickness TB1, TB3 of electrically insulating layer 31 and electrically insulating layer 33. The dielectric constant of electrically insulating layer 32 may be larger than each of dielectric constants of electrically insulating layer 31 and electrically insulating layer 33. In this case, the capacitance of MIM capacitor 13 per unit area can be increased. Thus, the area on main surface 21 required for wiring structure 10A can be reduced, and wiring structure 10A can be miniaturized.

Amplifier 1 of the embodiment includes capacitors 131 to 136 having the same structure as MIM capacitor 13 of wiring structure 10A, inductors 141 to 144 having the same structure as inductor 14 of wiring structure 10A, and transistor 11 provided on or above substrate 20 shared with wiring structure 10A. According to amplifier 1, it is possible to reduce a local increase in the electric field in capacitors 131 to 136 and to reduce the total number of wiring layers.

### Second Embodiment

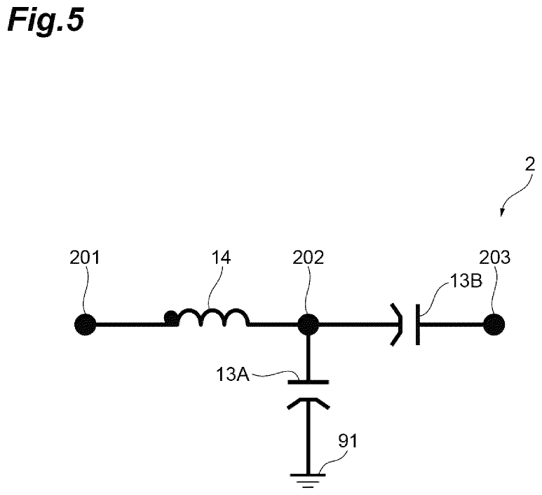

FIG. 5 is a circuit diagram of a passive element 2 according to a second embodiment. Passive element 2 is used as a matching circuit element connected to an amplifier, for example. Passive element 2 includes inductor 14 and two MIM capacitors 13A and 13B. One end of inductor 14 is connected to an input terminal 201, and the other end of inductor 14 is connected to a node 202. A first electrode of MIM capacitor 13A is connected to node 202. A second electrode of MIM capacitor 13A is connected to metal film 91 which is a reference potential line. A first electrode of MIM capacitor 13B is connected to node 202. A second electrode of MIM capacitor 13B is connected to an output terminal 203.

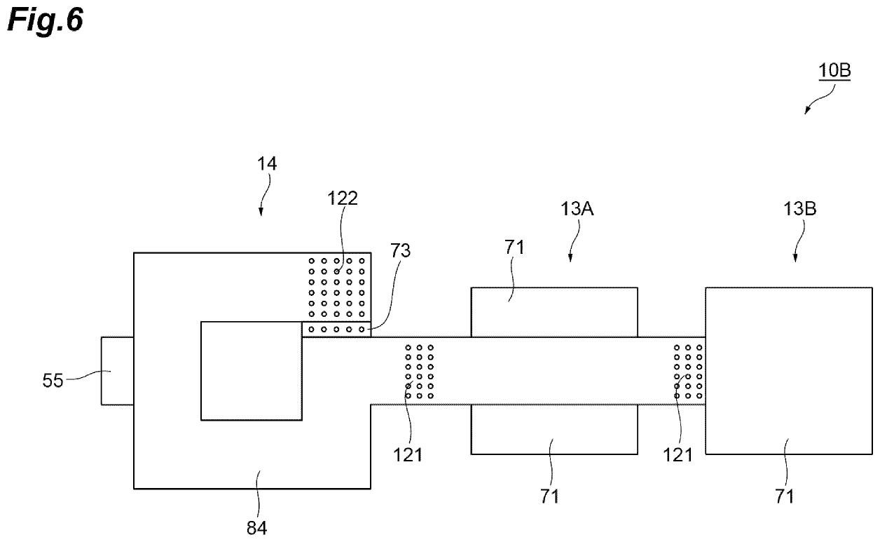

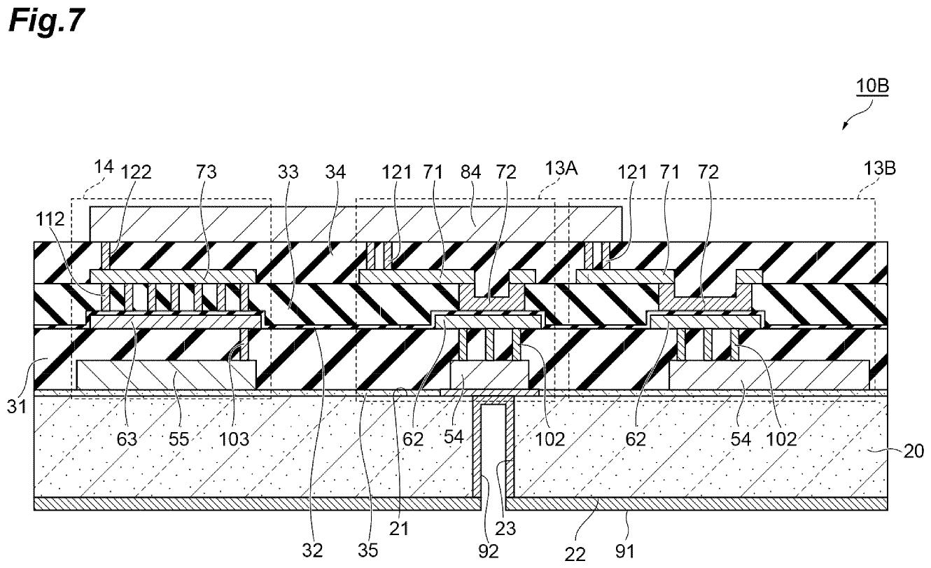

FIG. 6 is a plan view of a wiring structure 10B included in passive element 2. FIG. 7 is a diagram showing a cross-sectional structure of wiring structure 10B. As shown in FIGS. 6 and 7, inductor 14 and two MIM capacitors 13A and 13B are arranged on or above substrate 20 in this order along a predetermined direction. Inductor 14 has the same structure as inductor 14 of the first embodiment except for the following points. Inductor 14 of the embodiment includes a wiring 84 instead of wiring 83. Wiring 84 is included in fourth wiring layer 80. A thickness of wiring 84 is equal to or more than the thickness of wiring 55.

MIM capacitors 13A and 13B each have the same structure as MIM capacitor 13 of the first embodiment. Above MIM capacitor 13A, wiring 84 extending from inductor 14 is provided instead of wiring 82 of the first embodiment. Upper electrodes 72 of MIM capacitors 13A, 13B are connected to wiring 84 via wirings 71 and vias 121. Lower electrodes 62 of MIM capacitors 13A, 13B are connected to wirings 54 via vias 102, as in the first embodiment. Wiring 54 connected to MIM capacitor 13A is connected to metal film 91 via via 92, as in the first embodiment. On the other hand, unlike the first embodiment, via 92 is not connected to wiring 54 connected to MIM capacitor 13B.

Wiring 55 is connected to input terminal 201 shown in FIG. 5. Wiring 54 connected to MIM capacitor 13B is connected to output terminal 203 shown in FIG. 5. Node 202 shown in FIG. 5 is included in wiring 84.

According to wiring structure 10B of the embodiment, in the wiring structure including MIM capacitors 13A, 13B and inductor 14, it is possible to reduce a local increase in the electric field in MIM capacitors 13A, 13B and to reduce the total number of wiring layers, as in wiring structure 10A of the first embodiment.

The wiring structure and the amplifier according to the present disclosure are not limited to the above-described embodiments, and various modifications are possible. For example, in the above embodiment, the thickness relationships of first wiring layer 50, second wiring layer 60, third wiring layer 70, and fourth wiring layer 80 are mentioned, but these thickness relationships are not limited to the above relationships. In addition, in the above embodiment, the thickness relationships of electrically insulating layers 31, 32, 33 and 34 are mentioned, but these thickness relationships are not limited to the above relationships.

What is claimed is:

1. A wiring structure comprising a MIM capacitor and a helical wiring, comprising:
a substrate having a main surface and a back surface; and
a plurality of wiring layers sequentially stacked on or above the main surface,
wherein the plurality of wiring layers include a first wiring layer being a wiring layer closest to the substrate, a second wiring layer provided on or above the first wiring layer, and a third wiring layer provided on or above the second wiring layer,
wherein the MIM capacitor includes a first electrode included in the second wiring layer, a second electrode included in the third wiring layer, and a first electrically insulating layer provided between the first electrode and the second electrode, and
wherein the helical wiring includes a first wiring included in the first wiring layer, a second wiring included in the second wiring layer, and a third wiring included in the third wiring layer.

2. The wiring structure according to claim 1, further comprising:
a fourth wiring provided between the MIM capacitor and the substrate and included in the first wiring layer; and
one or more first vias connecting the first electrode to the fourth wiring.

3. The wiring structure according to claim 2, further comprising:
a metal film provided on the back surface; and
a second via provided to penetrate the substrate between the main surface and the back surface and connecting the metal film to the fourth wiring,
wherein the second via overlaps the MIM capacitor and the fourth wiring when viewed in a direction perpendicular to the main surface.

4. The wiring structure according to claim 1, wherein the helical wiring further includes a plurality of third vias disposed in a distributed manner over an entire region of the second wiring and the third wiring and connecting the second wiring to the third wiring.

5. The wiring structure according to claim 4, wherein each of thicknesses of the second wiring and the third wiring is smaller than a thickness of the first wiring.

6. The wiring structure according to claim 5, wherein a thickness of a wiring in the second wiring layer is smaller than a thickness of a wiring in the third wiring layer.

7. The wiring structure according to claim 5, wherein a sum of the thicknesses of the second wiring and the third wiring is equal to the thickness of the first wiring.

8. The wiring structure according to claim 4,
wherein the plurality of wiring layers further include a fourth wiring layer stacked on or above the third wiring layer, and
wherein the helical wiring further includes a fifth wiring included in the fourth wiring layer.

9. The wiring structure according to claim 8, wherein a thickness of the fifth wiring is equal to or more than a thickness of the first wiring.

10. The wiring structure according to claim 8,
wherein the first wiring, the second wiring, the third wiring, and the fifth wiring each have a ring shape partially having a gap, and are arranged such that centers of the ring shapes are located on a common axis perpendicular to the main surface,
wherein the gap of the second wiring and the gap of the third wiring are arranged in a direction perpendicular to the main surface, and
wherein the wiring structure further comprises
a fourth via connecting an end portion of the first wiring to an end portion of the second wiring, and
a fifth via connecting a second end portion of the third wiring located opposite to a first end portion of the third wiring located above the end portion of the second wiring to an end portion of the fifth wiring.

11. The wiring structure according to claim 1,
wherein the plurality of wiring layers further include a fourth wiring layer stacked on or above the third wiring layer, and
wherein the fourth wiring layer includes a sixth wiring provided above the MIM capacitor.

12. The wiring structure according to claim 1, further comprising:
a second electrically insulating layer interposed between the first wiring layer and the second wiring layer; and
a third electrically insulating layer interposed between the second wiring layer and the third wiring layer,
wherein a thickness of the first electrically insulating layer is smaller than each of thicknesses of the second electrically insulating layer and the third electrically insulating layer, and
wherein a dielectric constant of the first electrically insulating layer is larger than each of dielectric constants of the second electrically insulating layer and the third electrically insulating layer.

13. An amplifier comprising:
the wiring structure according to claim 1; and
a transistor provided on or above the substrate shared with the wiring structure.
